(19) United States
(12) Patent Application Publication
(10) Pub. No.: US 2022/0388194 A1
(43) Pub. Date: Dec. 8, 2022

(54) CUTTING BLADE REPLACEMENT APPARATUS

(71) Applicant: DISCO CORPORATION, Tokyo (JP)

(72) Inventors: Zhibo SU, Tokyo (JP); Shun NAKAGAWA, Tokyo (JP); Yoshimi KIMURA, Tokyo (JP)

(21) Appl. No.: 17/804,704

(22) Filed: May 31, 2022

(30) Foreign Application Priority Data
Jun. 7, 2021 (JP) 2021-094996

(51) Int. Cl. B27B 5/32; B26D 7/26

(52) U.S. Cl. CPC B27B 5/32; B26D 7/2621

(57) ABSTRACT

A cutting blade replacement apparatus includes a nut attaching-detaching unit including a nut holding part that holds a nut and a drive part that rotates the nut holding part. When the nut is screwed to a male screw formed at an end part of a boss part of a cutting unit, one of the nut attaching-detaching unit or the cutting unit moves in a Y-axis direction in synchronization with the speed of movement in the Y-axis direction due to the screwing of the nut, and the other of the nut attaching-detaching unit and the cutting unit escapes in the Y-axis direction when a pressing force equal to or larger than a predetermined value acts on the nut attaching-detaching unit or the cutting unit.

### BACKGROUND OF THE INVENTION

### Field of the Invention

The present invention relates to a cutting blade replacement apparatus that attaches and detaches a cutting blade.

### Description of the Related Art

A wafer on which plural devices such as integrated circuits (ICs) and large-scale integrated (LSI) circuits are formed on a surface in such a manner as to be marked out by planned dividing lines is divided into individual device chips by a cutting apparatus, and the respective device chips obtained by the dividing are used for pieces of electrical equipment such as mobile phones and personal computers.

The cutting apparatus includes a chuck table including a holding surface that holds a wafer, a cutting unit that supports a cutting blade that cuts the wafer held by the chuck table, an X-axis feed mechanism that executes processing feed of the chuck table in an X-axis direction, a Y-axis feed mechanism that executes indexing feed of the cutting unit in a Y-axis direction orthogonal to the X-axis direction, and a Z-axis feed mechanism that executes cutting-in feed of the cutting unit in a Z-axis direction orthogonal to each of the X-axis direction and the Y-axis direction. The holding surface of the chuck table is configured substantially in parallel to the plane defined by the X-axis direction and the Y-axis direction, and the wafer can be divided into the individual device chips with high accuracy.

The cutting unit has a configuration in which a flange is disposed at the tip of a spindle, a boss part that protrudes from the center of the flange is inserted in a central opening part of the cutting blade, and a nut is screwed to a male screw formed at the end part of the boss part to mount the cutting blade.

In recent years, an automatic replacement apparatus that can automatically replace the cutting blade mounted in the cutting unit of such a cutting apparatus has been proposed (for example, refer to Japanese Patent Laid-open No. 2007-98536).

### SUMMARY OF THE INVENTION

However, in the screwing of the nut to the male screw of the boss part, there is a problem that, if the center of the boss part deviates from the center of the nut, the male screw and the nut do not properly mesh with each other and “galling” occurs between the male screw and the nut. Furthermore, there is also a problem that a load is applied to the nut and the nut wears.

Thus, an object of the present invention is to provide a cutting blade replacement apparatus that can prevent the occurrence of galling between a male screw of a boss part and a nut and that can alleviate the load applied to the nut when the nut is screwed to the male screw of the boss part.

In accordance with an aspect of the present invention, there is provided a cutting blade replacement apparatus mounted on a cutting apparatus including a chuck table that holds a workpiece, a cutting unit in which a cutting blade that cuts the workpiece held by the chuck table is mounted, an X-axis feed mechanism that executes processing feed in an X-axis direction, and a Y-axis feed mechanism that executes indexing feed in a Y-axis direction orthogonal to the X-axis direction. The cutting blade replacement apparatus is capable of attaching and detaching the cutting blade to and from the cutting unit. The cutting unit has a spindle with a tip at which a flange is disposed and is configured in such a manner that mounting of the cutting blade is allowed by inserting a boss part that protrudes from the center of the flange into a central opening part of the cutting blade and screwing a nut to a male screw formed at an end part of the boss part. The cutting blade replacement apparatus includes a nut attaching-detaching unit including a nut holding part that holds the nut and a drive part that rotates the nut holding part. When the nut is screwed to the male screw formed at the end part of the boss part, one of the nut attaching-detaching unit or the cutting unit moves in the Y-axis direction in synchronization with the speed at which the boss part and the nut relatively move in the Y-axis direction due to the screwing of the nut, and the other of the nut attaching-detaching unit and the cutting unit escapes in the Y-axis direction when a pressing force equal to or larger than a predetermined value acts on the nut attaching-detaching unit or the cutting unit.

Preferably, a warning is issued when the nut is not screwed.

The cutting blade replacement apparatus according to the aspect of the present invention includes the nut attaching-detaching unit including the nut holding part that holds the nut and the drive part that rotates the nut holding part. When the nut is screwed to the male screw formed at the end part of the boss part, one of the nut attaching-detaching unit or the cutting unit moves in the Y-axis direction in synchronization with the speed at which the boss part and the nut relatively move in the Y-axis direction due to the screwing of the nut, and the other of the nut attaching-detaching unit and the cutting unit escapes in the Y-axis direction when the pressing force equal to or larger than the predetermined value acts on the nut attaching-detaching unit or the cutting unit. Therefore, when the nut is screwed to the male screw of the boss part, the occurrence of galling between the male screw of the boss part and the nut can be prevented, and the load applied to the nut can be alleviated.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting blade replacement apparatus according to an embodiment;

FIG. 2 is an exploded perspective view of a cutting blade storage unit illustrated in FIG. 1;

FIG. 3 is a perspective view of a support shaft illustrated in FIG. 2;

FIG. 4 is a sectional view of the support shaft illustrated in FIG. 2;

FIG. 5 is a perspective view of a nut attaching-detaching unit illustrated in FIG. 1;

FIG. 6 is an exploded perspective view of a frame body, a raising-lowering table, and a base stand illustrated in FIG. 1;

FIG. 7 is an exploded perspective view of the frame body illustrated in FIG. 1;

FIG. 8 is a perspective view of a cutting apparatus on which the cutting blade replacement apparatus illustrated in FIG. 1 is mounted;

FIG. 9 is a perspective view of a chuck table illustrated in FIG. 8;

FIG. 10 is a perspective view of cutting units illustrated in FIG. 8;

FIG. 11 is a perspective view of the cutting unit in a state in which a blade cover illustrated in FIG. 10 is opened;

FIG. 12 is an exploded perspective view of the cutting unit illustrated in FIG. 8;

FIG. 13 is a perspective view illustrating a state in which the cutting blade replacement apparatus illustrated in FIG. 1 is mounted on the cutting apparatus illustrated in FIG. 8;

FIG. 14 is a perspective view illustrating a state in which the cutting blade storage unit of the cutting blade replacement apparatus illustrated in FIG. 1 and the nut attaching-detaching unit face each other;

FIG. 15 is a perspective view illustrating a state in which the frame body has advanced toward the cutting blade storage unit from the state illustrated in FIG. 14;

FIG. 16 is a perspective view illustrating a state in which the frame body has retreated and the raising-lowering table has risen from the state illustrated in FIG. 15;

FIG. 17 is a perspective view illustrating a state in which a first moving body has advanced toward the cutting apparatus from the state illustrated in FIG. 16;

FIG. 18 is a perspective view illustrating a state in which a second moving body has advanced toward the cutting apparatus from the state illustrated in FIG. 17;

FIG. 19 is a perspective view illustrating a state in which a nut holding part that holds a nut is caused to face a boss part of a spindle;

FIG. 20 is a perspective view illustrating a state in which the nut held by the nut holding part is being attached to the boss part of the spindle; and

FIG. 21 is a perspective view illustrating a state in which the nut has been attached to the boss part of the spindle.

### DETAILED DESCRIPTION OF THE PREFERRED EMBODIMENT

An embodiment of the present invention will be described below with reference to the accompanying drawings.

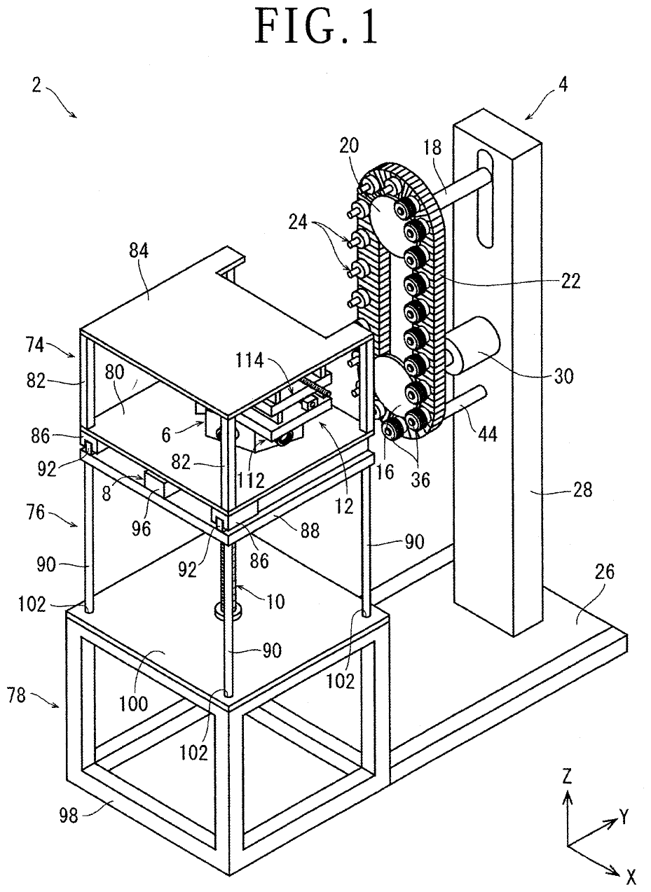

Referring to FIG. 1, a cutting blade replacement apparatus totally illustrated by the reference sign 2 includes at least a cutting blade storage unit 4 that stores plural cutting blades, a nut attaching-detaching unit 6 that carries out and carries in the cutting blade from and to the cutting blade storage unit 4, a Y-axis direction positioning mechanism 8 that positions the nut attaching-detaching unit 6 to an operation position and an evacuation position in the Y-axis direction relative to the cutting blade storage unit 4, a Z-axis movement mechanism 10 that moves the nut attaching-detaching unit 6 in a Z-axis direction, and an X-axis movement mechanism 12 that moves the nut attaching-detaching unit 6 in an X-axis direction and acts on the cutting blade mounted on a spindle of a cutting unit of a cutting apparatus.

The X-axis direction is a direction indicated by an arrow X in FIG. 1. The Y-axis direction is a direction indicated by an arrow Y in FIG. 1 and is a direction orthogonal to the X-axis direction. The Z-axis direction is a direction indicated by an arrow Z in FIG. 1 and is the upward-downward direction orthogonal to the X-axis direction and the Y-axis direction. Furthermore, the plane defined by the X-axis direction and the Y-axis direction is substantially horizontal.

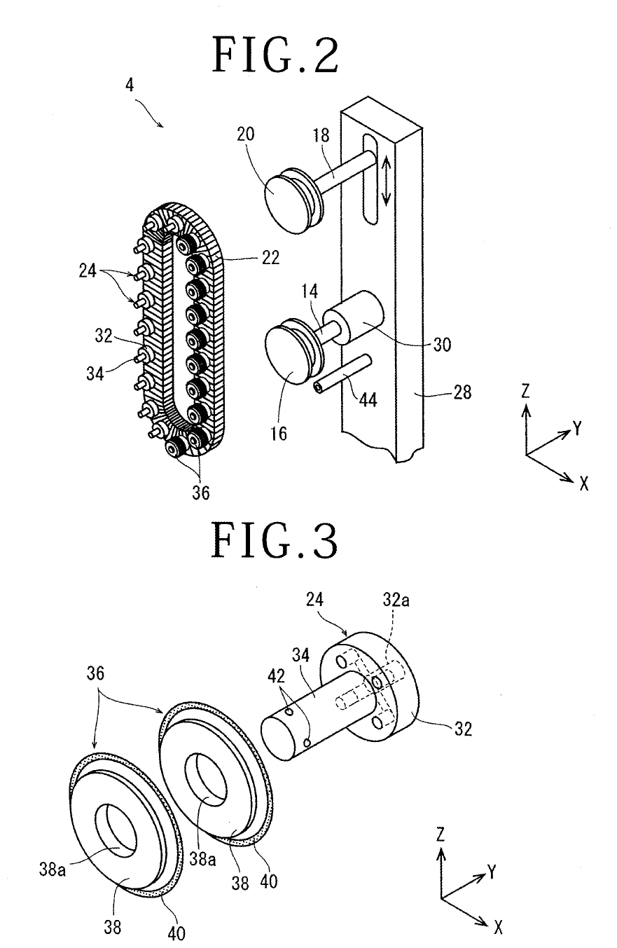

As illustrated in FIG. 2, the cutting blade storage unit 4 includes a drive gear 16 having a rotating shaft 14 extending in the Y-axis direction, a driven gear 20 that is separate from the drive gear 16 in the Z-axis direction and has a rotating shaft 18 extending in the Y-axis direction, an endless track 22 wound around the drive gear 16 and the driven gear 20, and support shafts 24 that are disposed on the endless track 22 at predetermined intervals and are inserted into a central opening part of the cutting blade to support the cutting blade and extend in the Y-axis direction.

Referring to FIG. 1 and FIG. 2, the cutting blade storage unit 4 of the illustrated embodiment includes a base plate 26 (see FIG. 1), a support wall 28 that extends upward from the upper surface of the base plate 26, and a motor 30 fixed to a single surface of the support wall 28. As illustrated in FIG. 2, the rotating shaft 14 of the drive gear 16 is coupled to the motor 30, and the motor 30 rotates the drive gear 16 with the Y-axis direction being the axial center.

As illustrated in FIG. 2, the driven gear 20 is disposed above the drive gear 16, and the rotating shaft 18 of the driven gear 20 is supported by the support wall 28 in such a manner as to be capable of rotating with the Y-axis direction being the axial center and rising and lowering in the Z-axis direction. A raising-lowering mechanism (not illustrated) that raises and lowers the driven gear 20 in the Z-axis direction is disposed on the support wall 28. For example, the raising-lowering mechanism has a ball screw that is coupled to the rotating shaft 18 of the driven gear 20 and extends in the Z-axis direction and a motor that rotates this ball screw.

The endless track 22 includes a large number of link pieces (the reference sign is omitted) that are mutually coupled and is wound around the drive gear 16 and the driven gear 20. The endless track 22 rotates in response to rotation of the drive gear 16 by the motor 30.

In the cutting blade storage unit 4 of the illustrated embodiment, the interval between the drive gear 16 and the driven gear 20 in the Z-axis direction can be adjusted by changing the position of the driven gear 20 in the Z-axis direction by the raising-lowering mechanism. Furthermore, in the cutting blade storage unit 4, the length of the endless track 22 can also be adjusted by increasing or decreasing the number of link pieces of the endless track 22 as appropriate.

As illustrated in FIG. 2, the plural support shafts 24 are disposed on the endless track 22 at predetermined intervals. Furthermore, as is understood through referring to FIG. 3 with FIG. 2, each of the support shafts 24 has a base part 32 that is coupled to the endless track 22 and has a circular column shape and a shaft part 34 that extends in the Y-axis direction from an end surface of the base part 32 and has a circular column shape. The diameter of the shaft part 34 is smaller than that of the base part 32.

In FIG. 3, cutting blades 36 supported by the support shaft 24 are also illustrated. The cutting blades 36 each have an annular base 38 and an annular cutting edge 40 fixed to the outer circumferential part of the base 38. The base 38 can be formed from an appropriate metal material such as an aluminum alloy. A circular central opening part 38a is provided at the central part of the base 38. The cutting edge 40 is formed into a predetermined thickness (for example, approximately 10 to 30 μm) from abrasive grains of diamond or the like and a bond of a metal, resin, or the like and protrudes outward in the radial direction from the outer circumferential edge of the base 38.

In the support shaft 24, the shaft part 34 is inserted into the central opening part 38a of the cutting blade 36 and plural (for example, five) cutting blades 36 are supported by the shaft part 34. In the illustrated embodiment, as is understood through referring to FIG. 2, the cutting blades 36 are supported by half of the plural support shafts 24. Furthermore, as illustrated in FIG. 3, at the tip side of the shaft part 34, plural ball plungers 42 for preventing dropping-off of the cutting blade 36 supported by the shaft part 34 are mounted at intervals in the circumferential direction.

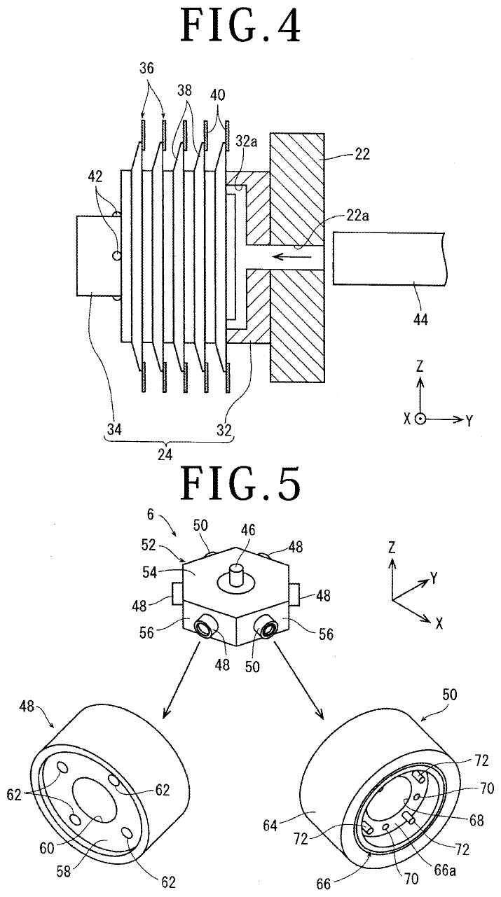

As illustrated in FIG. 4, a flow path 32a is formed inside each base part 32 of the support shaft 24, and plural flow paths 22a that each communicate with one end part of a respective one of the flow paths 32a are formed in the endless track 22. As illustrated in FIG. 3, the other end part of each flow path 32a is opened at the end surface of the base part 32 on the outside in the radial direction relative to the shaft part 34.

Furthermore, as illustrated in FIG. 2, an air nozzle 44 that protrudes in the Y-axis direction below the drive gear 16 is disposed on the support wall 28, and the air nozzle 44 is connected to a high-pressure air supply source (not illustrated). In the illustrated embodiment, the support shaft 24 located at the lowermost position in the trajectory of the support shafts 24 in association with the rotation of the endless track 22 faces the tip of the air nozzle 44.

Moreover, when the cutting blade 36 located on the tip side of the shaft part 34 is carried out, the cutting blades 36 left on the shaft part 34 can be pushed out toward the tip side of the shaft part 34 by supplying high-pressure air to the flow path 32a of the base part 32 of the support shaft 24 located at the lowermost position from the air nozzle 44 through the flow path 22a of the endless track 22. However, the cutting blades 36 does not drop from the shaft part 34 due to operation of the ball plungers 42.

The nut attaching-detaching unit 6 will be described with reference to FIG. 5. The nut attaching-detaching unit 6 includes at least a Z rotating shaft 46 that extends in the Z-axis direction, blade holding parts 48 that are coupled to the Z rotating shaft 46 in a radial manner and hold the cutting blade 36 under suction, nut holding parts 50 that hold a nut, and a drive part (not illustrated) that rotates the nut holding part 50.

As illustrated in FIG. 5, the nut attaching-detaching unit 6 of the illustrated embodiment further includes a casing 52. The casing 52 has a top plate 54 with a regular hexagonal shape and six sidewalls 56 that hang down from the circumferential edge of the top plate 54 and have a rectangular plate shape. The above-described Z rotating shaft 46 protrudes from the upper surface of the top plate 54. A motor (not illustrated) coupled to the Z rotating shaft 46 is housed inside the casing 52.

In the illustrated embodiment, the blade holding parts 48 are mounted on four sidewalls 56 in the six sidewalls 56 of the casing 52, and the nut holding parts 50 are mounted on two sidewalls 56. The two nut holding parts 50 are disposed on a pair of sidewalls 56 opposed to each other. As above, the nut attaching-detaching unit 6 includes two blade holding parts 48 per one nut holding part 50.

The blade holding part 48 is formed into a cylindrical shape. In an end surface 58 of the blade holding part 48, provided are a circular central opening part 60 that can accept the shaft part 34 of the above-described support shaft 24 and a boss part of the spindle of the cutting apparatus and plural suction holes 62 disposed around the central opening part 60 at equal intervals in the circumferential direction. Each suction hole 62 is connected to a suction source (not illustrated) such as a vacuum pump.

In the blade holding part 48, the cutting blade 36 is held under suction by generating a suction force for each suction hole 62 by the suction source in a state in which the blade holding part 48 is positioned at a position at which the end surface 58 of the blade holding part 48 gets contact with the base 38 of the cutting blade 36 stored in the cutting blade storage unit 4.

The description will be continued with reference to FIG. 5. The nut holding part 50 includes a cylindrical housing 64 fixed to the sidewall 56 of the casing 52 and an annular rotating body 66 that is rotatably housed inside the housing 64 and is rotated by the above-described drive part.

In the rotating body 66, a central opening part 68 that can accept the boss part of the spindle of the cutting apparatus is formed. In an end surface 66a of the rotating body 66, plural suction holes 70 and plural pins 72 are alternately disposed at intervals in the circumferential direction. Each suction hole 70 is connected to a suction source (not illustrated). The pins 72 are positioned at such positions (positions illustrated in FIG. 5) as to protrude from the end surface 66a of the rotating body 66 by a spring (not illustrated) incorporated in the rotating body 66. In addition, when being pressed toward the inside of the rotating body 66, the pins 72 are housed inside the rotating body 66 through contraction of the spring. Furthermore, the pins 72 are disposed corresponding to the positions of pin holes formed in the nut.

In the nut attaching-detaching unit 6, the nut for fixing the cutting blade 36 to the spindle of the cutting apparatus can be screwed to and unscrewed (detached) from a male screw formed in the boss part of the spindle by rotating the rotating body 66 by the drive part in a state in which a suction force is generated for each suction hole 70 by the suction source to hold the nut under suction by the nut holding part 50 and the pins 72 are inserted in the pin holes formed in the nut.

In a case in which the positions of the pins 72 of the nut holding part 50 deviate from the positions of the pin holes of the nut when the nut is unscrewed (detached) from the boss part of the spindle, if the rotating body 66 is rotated by the drive part after the end surface 66a of the rotating body 66 is positioned to the end surface of the nut mounted on the boss part of the spindle and the pins 72 are housed inside the rotating body 66, the pins 72 are pushed out by the spring when the positions of the pins 72 are aligned with the positions of the pin holes, so that the pins 72 are inserted into the pin holes.

The nut attaching-detaching unit 6 that can be configured as described above is disposed inside a frame body 74 as illustrated in FIG. 1 in the illustrated embodiment. The frame body 74 is supported by a raising-lowering table 76 movably in the Y-axis direction, and the raising-lowering table 76 is supported by a base stand 78 in such a manner as to be capable of rising and lowering in the Z-axis direction.

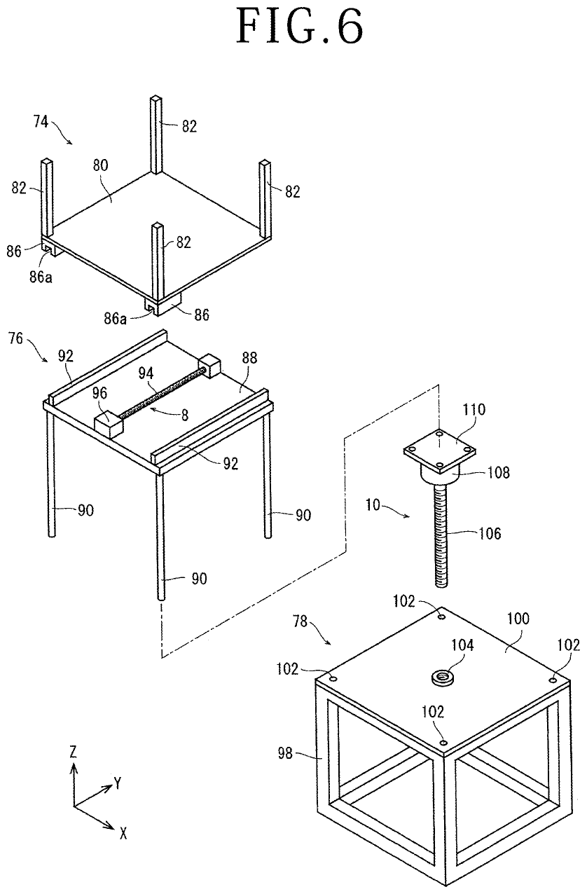

Referring to FIG. 6 with FIG. 1, the frame body 74 includes a bottom part 80 with a rectangular plate shape, four support columns 82 that extend upward from four corners of the upper surface of the bottom part 80, and a plate-shaped ceiling part 84 (see FIG. 1) fixed to the upper ends of the respective support columns 82. On the lower surface of the bottom part 80, a pair of guided components 86 in which grooves 86a extending in the Y-axis direction are formed are disposed at an interval in the X-axis direction.

The raising-lowering table 76 includes a rectangular top plate 88 and four circular columnar leg parts 90 that extend downward from four corners of the lower surface of the top plate 88. A pair of guide rails 92 that extend in the Y-axis direction with the interposition of an interval in the X-axis direction are disposed on the upper surface of the top plate 88, and the pair of guide rails 92 are slidably fitted into the grooves 86a of the pair of guided components 86 of the frame body 74.

Furthermore, the Y-axis direction positioning mechanism 8 is disposed on the upper surface of the top plate 88 of the raising-lowering table 76. The Y-axis direction positioning mechanism 8 has a ball screw 94 that extends in the Y-axis direction between the pair of guide rails 92 and a motor 96 that rotates the ball screw 94. A nut part (not illustrated) of the ball screw 94 is fixed to the lower surface of the bottom part 80 of the frame body 74.

The Y-axis direction positioning mechanism 8 converts rotational motion of the motor 96 to linear motion by the ball screw 94 and transmits the linear motion to the frame body 74 to move the frame body 74 in the Y-axis direction along the pair of guide rails 92. As above, the frame body 74 in which the nut attaching-detaching unit 6 is disposed is slidably supported by the guide rails 92 that are disposed on the raising-lowering table 76 and extend in the Y-axis direction, and the nut attaching-detaching unit 6 is positioned to the operation position and the evacuation position in the Y-axis direction relative to the cutting blade storage unit 4 by the Y-axis direction positioning mechanism 8.

The above-described operation position is a position at which the blade holding part 48 of the nut attaching-detaching unit 6 is close to the cutting blade storage unit 4 and is a position at which the cutting blade 36 supported by the cutting blade storage unit 4 can be held under suction by the blade holding part 48. Furthermore, the above-described evacuation position is a position at which the blade holding part 48 of the nut attaching-detaching unit 6 is more separate from the cutting blade storage unit 4 than at the above-described operation position.

Moreover, the Y-axis direction positioning mechanism 8 of the illustrated embodiment is configured in such a manner that, when the motor 96 has stopped, movement of the nut attaching-detaching unit 6 in the Y-axis direction together with the frame body 74 is permitted if a pressing force equal to or larger than a predetermined value acts on the nut attaching-detaching unit 6 in the Y-axis direction.

As illustrated in FIG. 6, the base stand 78 includes a frame 98 and a rectangular base plate 100 fixed to the upper part of the frame 98. Four circular holes 102 into which the leg parts 90 of the raising-lowering table 76 are slidably inserted are formed at four corners of the base plate 100. Furthermore, a female screw 104 is formed at the central part of the base plate 100.

The description will be continued with reference to FIG. 6. The Z-axis movement mechanism 10 is coupled to the raising-lowering table 76 and the base stand 78. The Z-axis movement mechanism 10 includes a ball screw 106 that extends in the Z-axis direction, a motor 108 that rotates the ball screw 106, and a coupling plate 110 fixed to the upper end of the motor 108. The ball screw 106 is screwed to the female screw 104 of the base plate 100. The coupling plate 110 is fixed to the lower surface of the top plate 88 of the raising-lowering table 76 by an appropriate coupling implement such as a bolt (not illustrated).

The Z-axis movement mechanism 10 moves the frame body 74 in which the nut attaching-detaching unit 6 is disposed in the Z-axis direction by converting rotational motion of the motor 108 to linear motion by the ball screw 106 and raising or lowering the raising-lowering table 76 relative to the base stand 78.

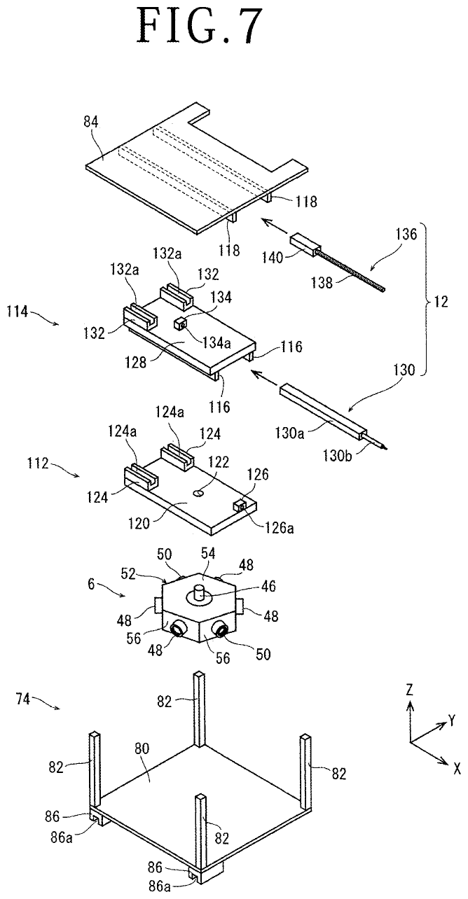

Referring to FIG. 7, the nut attaching-detaching unit 6 is disposed on a first moving body 112 disposed inside the frame body 74. The first moving body 112 is slidably supported in a state in which it is hung down by first guide rails 116 that are disposed at the lower part of a second moving body 114 and extend in the X-axis direction. The second moving body 114 is slidably supported in a state in which it is hung down by second guide rails 118 that are disposed on the ceiling part 84 of the frame body 74 and extend in the X-axis direction.

The first moving body 112 has a main body 120 with a rectangular plate shape. A circular hole 122 is formed at the central part of the main body 120. The Z rotating shaft 46 of the nut attaching-detaching unit 6 is inserted in the circular hole 122, and the Z rotating shaft 46 is non-rotatably fixed to the main body 120. When the motor of the nut attaching-detaching unit 6 coupled to the Z rotating shaft 46 is driven, the casing 52 of the nut attaching-detaching unit 6 rotates relative to the first moving body 112, and the blade holding parts 48 and the nut holding parts 50 are positioned in given orientations.

On the upper surface of the main body 120 of the first moving body 112, a pair of guided components 124 in which grooves 124a that extend in the X-axis direction are formed are disposed at an interval in the Y-axis direction, and a block 126 in which a through-hole 126a that extends in the X-axis direction is formed is fixed.

The second moving body 114 has a main body 128 with a rectangular plate shape, and the pair of first guide rails 116 are disposed on the lower surface of the main body 128 at an interval in the Y-axis direction. The first guide rails 116 are slidably fitted into the grooves 124a of the pair of guided components 124 of the first moving body 112, and the first moving body 112 is slidably supported in a state in which it is hung down by the first guide rails 116 disposed in the second moving body 114.

A first X-axis movement mechanism that moves the first moving body 112 in the X-axis direction relative to the second moving body 114 is disposed under the main body 128 of the second moving body 114. The first X-axis movement mechanism of the illustrated embodiment includes an air cylinder 130. A cylinder tube 130a of the air cylinder 130 is fixed to the lower surface of the main body 128 and extends in the X-axis direction between the pair of first guide rails 116. The tip of a piston rod 130b of the air cylinder 130 is fitted and coupled to the through-hole 126a of the block 126 of the first moving body 112.

The air cylinder 130 as the first X-axis movement mechanism moves the first moving body 112 in the X-axis direction along the first guide rails 116 relative to the second moving body 114 by causing the piston rod 130b to advance and retreat.

On the upper surface of the main body 128 of the second moving body 114, a pair of guided components 132 in which grooves 132a that extend in the X-axis direction are formed are disposed at an interval in the Y-axis direction, and a block 134 in which a female screw 134a that extends in the X-axis direction is formed is fixed.

The pair of second guide rails 118 are disposed on the lower surface of the ceiling part 84 of the frame body 74 at an interval in the Y-axis direction. The second guide rails 118 are slidably fitted into the grooves 132a of the pair of guided components 132 of the second moving body 114, and the second moving body 114 is slidably supported in a state in which it is hung down by the second guide rails 118 disposed on the lower surface of the ceiling part 84.

A second X-axis movement mechanism 136 that moves the second moving body 114 in the X-axis direction relative to the ceiling part 84 is disposed under the ceiling part 84 of the frame body 74. The second X-axis movement mechanism 136 of the illustrated embodiment has a ball screw 138 that extends in the X-axis direction between the pair of second guide rails 118 and a motor 140 that rotates the ball screw 138. The ball screw 138 is screwed to the female screw 134a of the block 134 of the second moving body 114, and the motor 140 is fixed to the lower surface of the ceiling part 84.

The second X-axis movement mechanism 136 converts rotational motion of the motor 140 to linear motion by the ball screw 138 and transmits the linear motion to the second moving body 114 to move the second moving body 114 in the X-axis direction along the second guide rails 118 relative to the ceiling part 84.

The X-axis movement mechanism 12 of the illustrated embodiment includes the air cylinder 130 as the first X-axis movement mechanism and the second X-axis movement mechanism 136 having the ball screw 138 and the motor 140. In the illustrated embodiment, the nut attaching-detaching unit 6 can be caused to quickly advance in the X-axis direction by moving the first moving body 112 by the air cylinder 130 as the first X-axis movement mechanism. In addition, fine adjustment of the position of the nut attaching-detaching unit 6 in the X-axis direction can be easily executed by moving the second moving body 114 by the second X-axis movement mechanism 136. As above, the nut attaching-detaching unit 6 is configured to be capable of advancing in the X-axis direction by the first moving body 112 and the second moving body 114.

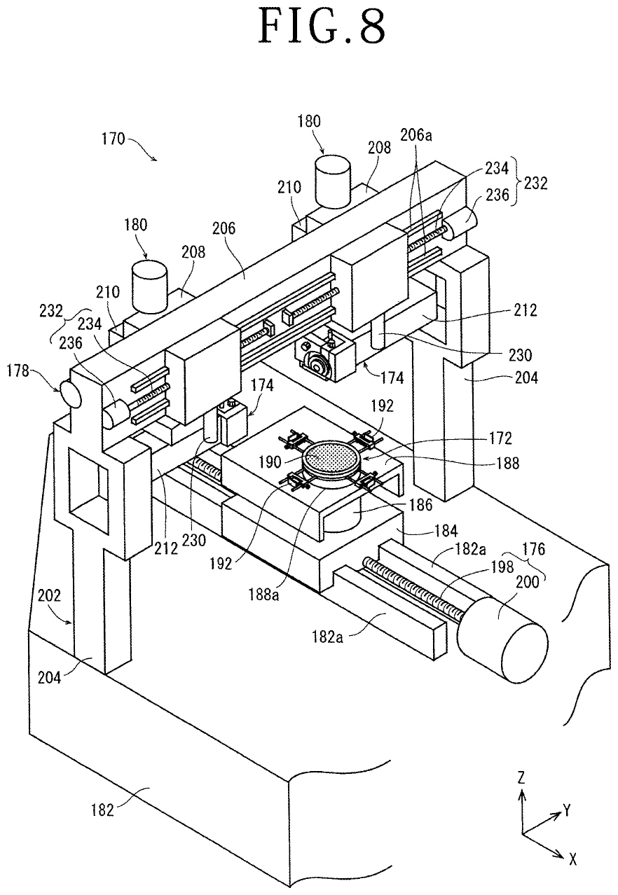

Next, with reference to FIG. 8 to FIG. 13, a cutting apparatus 170 on which the above-described cutting blade replacement apparatus 2 is mounted will be described.

As illustrated in FIG. 8, the cutting apparatus 170 includes a chuck table 172 that holds a workpiece, cutting units 174 in which cutting blades that cut the workpiece held by the chuck table 172 are mounted, an X-axis feed mechanism 176 that executes relative movement (processing feed) of the chuck table 172 and the cutting units 174 in the X-axis direction, Y-axis feed mechanisms 178 that execute relative movement (indexing feed) of the chuck table 172 and the cutting unit 174 in the Y-axis direction orthogonal to the X-axis direction, and Z-axis feed mechanisms 180 that execute cutting-in feed of the cutting unit 174 in the Z-axis direction orthogonal to each of the X-axis direction and the Y-axis direction.

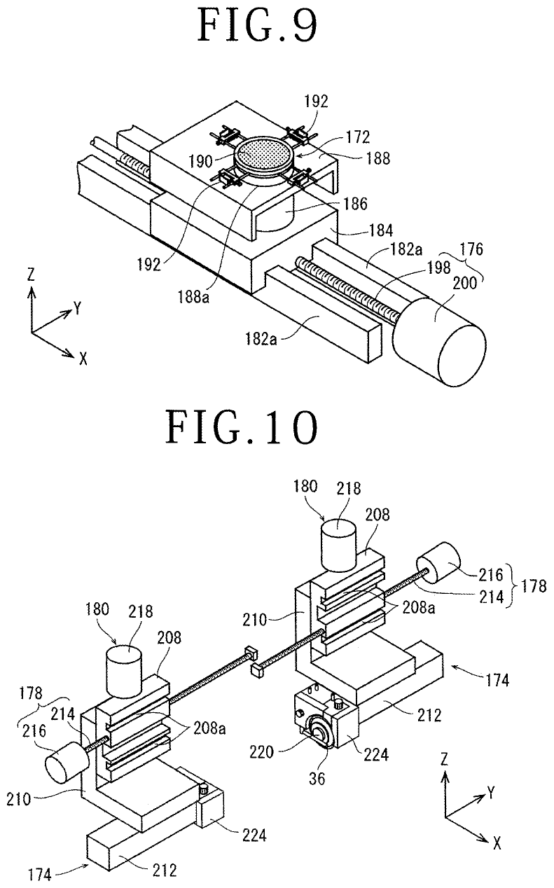

Referring to FIG. 8 and FIG. 9, the cutting apparatus 170 includes an X-axis movable plate 184 disposed over the upper surface of a base 182 (see FIG. 8) movably in the X-axis direction, a support column 186 fixed to the upper surface of the X-axis movable plate 184, and a cover plate 188 fixed to the upper end of the support column 186. A circular opening 188a is formed in the cover plate 188. The chuck table 172 is rotatably mounted on the upper end of the support column 186 and passes through the circular opening 188a of the cover plate 188 to extend upward. The chuck table 172 is rotated by a motor (not illustrated) incorporated in the support column 186 with the Z-axis direction being the axial center.

As illustrated in FIG. 9, a porous circular suction adhesion chuck 190 connected to a suction source (not illustrated) is disposed at the upper end part of the chuck table 172. The chuck table 172 holds a workpiece placed on the upper surface of the suction adhesion chuck 190 under suction by generating a suction force for the upper surface of the suction adhesion chuck 190 by the suction source. As above, in the chuck table 172, the upper surface of the suction adhesion chuck 190 serves as a holding surface that holds the workpiece, and the holding surface is positioned on the XY-plane defined by the X-axis direction and the Y-axis direction. Furthermore, plural clamps 192 are disposed at the circumferential edge of the chuck table 172 at intervals in the circumferential direction.

As illustrated in FIG. 9, the X-axis feed mechanism 176 has a ball screw 198 that is coupled to the X-axis movable plate 184 and extends in the X-axis direction and a motor 200 that rotates the ball screw 198. The X-axis feed mechanism 176 converts rotational motion of the motor 200 to linear motion by the ball screw 198 and transmits the linear motion to the X-axis movable plate 184 to move the X-axis movable plate 184 along guide rails 182a on the base 182 and execute processing feed of the chuck table 172 in the X-axis direction.

As illustrated in FIG. 8, the cutting apparatus 170 includes a gate-shaped frame 202 disposed astride the chuck table 172. The frame 202 has a pair of support columns 204 that extend upward from the upper surface of the base 182 with the interposition of an interval in the Y-axis direction and a beam 206 that is made to bridge the interval between the upper ends of the pair of support columns 204 and extends in the Y-axis direction.

The pair of cutting units 174 are disposed on a side surface of the beam 206 on a single side (side surface on the back side in FIG. 8) at an interval in the Y-axis direction. In the cutting apparatus 170 of the illustrated embodiment, the pair of cutting units 174 are disposed in such a manner that the cutting blades 36 face each other, and cutting processing of the workpiece held by the chuck table 172 can be executed by the pair of cutting blades 36 simultaneously. The number of cutting units 174 may be one.

As illustrated in FIG. 10, each cutting unit 174 includes a rectangular Y-axis movable component 208 supported by the side surface of the beam 206 on the single side movably in the Y-axis direction, a Z-axis movable component 210 that is supported by the Y-axis movable component 208 in such a manner as to be capable of rising and lowering in the Z-axis direction and has an L-shape as a sectional shape, and a spindle housing 212 fixed to the lower end of the Z-axis movable component 210.

A pair of guided grooves 208a that extend in the Y-axis direction with the interposition of an interval in the Z-axis direction are formed in a side surface of the Y-axis movable component 208 on a single side (side surface on the front side in FIG. 10), and the guided grooves 208a are slidably coupled to a pair of guide rails (not illustrated) that extend in the Y-axis direction on the side surface of the beam 206 on the single side with the interposition of an interval in the upward-downward direction.

The Y-axis feed mechanism 178 has a ball screw 214 that extends in the Y-axis direction near the side surface of the beam 206 on the single side and a motor 216 that rotates the ball screw 214. The ball screw 214 is coupled to the Y-axis movable component 208. The Y-axis feed mechanism 178 converts rotational motion of the motor 216 to linear motion by the ball screw 214 and transmits the linear motion to the Y-axis movable component 208 to execute indexing feed of the Y-axis movable component 208 in the Y-axis direction along the guide rails annexed to the side surface of the beam 206 on the single side.

Furthermore, the Y-axis feed mechanism 178 of the illustrated embodiment is configured in such a manner that, when the motor 216 has stopped, movement of the spindle housing 212 in the Y-axis direction together with the Y-axis movable component 208 is permitted if a pressing force equal to or larger than a predetermined value acts on the spindle housing 212 in the Y-axis direction.

A pair of guide rails (not illustrated) that extend in the Z-axis direction with the interposition of an interval in the Y-axis direction are formed on the side surface of the Y-axis movable component 208 on the other side (side surface on the back side in FIG. 10), and the Z-axis movable component 210 has a pair of guided grooves (not illustrated) slidably coupled to the pair of guide rails of the Y-axis movable component 208.

The Z-axis feed mechanism 180 has a ball screw (not illustrated) that is coupled to the Z-axis movable component 210 and extends in the Z-axis direction and a motor 218 that rotates this ball screw. The Z-axis feed mechanism 180 converts rotational motion of the motor 218 to linear motion by the ball screw and transmits the linear motion to the Z-axis movable component 210 to execute cutting-in feed of the Z-axis movable component 210 in the Z-axis direction along the guide rails of the Y-axis movable component 208.

Referring to FIG. 11, a circular columnar spindle 220 is supported by the spindle housing 212 in such a manner as to be capable of rotating with the Y-axis direction being the axial center. In addition, a motor (not illustrated) that rotates the spindle 220 is housed in the spindle housing 212. The cutting blade 36 that cuts a workpiece is fixed to the tip of the spindle 220 attachably and detachably by a nut 222.

A blade cover 224 that covers the cutting blade 36 is mounted on the tip of the spindle housing 212. The blade cover 224 has a first cover component 224a fixed to the tip of the spindle housing 212 and a second cover component 224b movably mounted on the tip of the first cover component 224a. The second cover component 224b is configured to be moved in the X-axis direction by an appropriate actuator (not illustrated) such as an air cylinder. The second cover component 224b is positioned at an opening position illustrated in FIG. 11 at the time of replacement of the cutting blade 36 and is positioned to a closing position illustrated in FIG. 10 at the time of cutting processing.

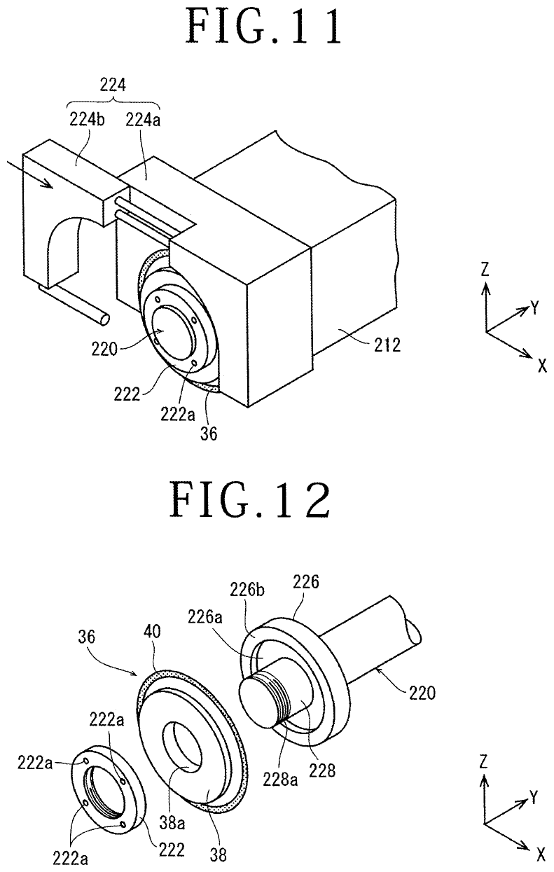

As illustrated in FIG. 12, an annular flange 226 that protrudes outward in the radial direction is disposed on the outer circumferential surface of the spindle 220 on the tip side. An annular recess 226a is formed at an inside part in the radial direction in the tip surface of the flange 226, and a part on the outer circumferential side in the tip surface of the flange 226 is an annular receiving part 226b that protrudes in the axial direction. Furthermore, a boss part 228 that protrudes from the center of the flange 226 is disposed on the side closer to the tip than the flange 226. A male screw 228a is formed in the outer circumferential surface of the tip part of the boss part 228.

The boss part 228 is inserted in the central opening part 38a of the cutting blade 36, and the male screw 228a of the boss part 228 and the nut 222 are screwed to each other (fitted to each other). Thereby, the cutting blade 36 is clamped by the receiving part 226b of the flange 226 and the nut 222 and is fixed to the boss part 228 attachably and detachably. Moreover, in a side surface of the nut 222, plural pin holes 222a into which the pins 72 of the nut holding part 50 of the nut attaching-detaching unit 6 are inserted are formed at equal intervals in the circumferential direction.

As illustrated in FIG. 8, on the side surface of the beam 206 of the frame 202 on the other side (side surface on the front side in FIG. 8), a pair of imaging units 230 that image a workpiece held by the chuck table 172 are mounted movably in the Y-axis direction, and a pair of movement mechanisms 232 that move the imaging unit 230 in the Y-axis direction are mounted.

The movement mechanism 232 has a ball screw 234 that extends in the Y-axis direction near the side surface of the beam 206 on the other side and a motor 236 that rotates the ball screw 234. The ball screw 234 is coupled to the imaging unit 230. Furthermore, the movement mechanism 232 converts rotational motion of the motor 236 to linear motion and transmits the linear motion to the imaging unit 230 to move the imaging unit 230 in the Y-axis direction along guide rails 206a annexed to the side surface of the beam 206 on the other side. The imaging units 230 are cameras including an imaging element, an optical system, and so forth, for example. The number of imaging units 230 may be one.

When cutting processing is executed for a workpiece such as a wafer by using the cutting apparatus 170, first, suction adhesion of the workpiece to the chuck table 172 is caused. Subsequently, the chuck table 172 is moved to the lower side of the imaging unit 230 by the X-axis feed mechanism 176. In addition, the position of the imaging unit 230 in the Y-axis direction is adjusted by the movement mechanism 232. Next, the workpiece is imaged from the upper side by the imaging unit 230, and a cutting region in the workpiece is detected.

Subsequently, on the basis of the cutting region in the workpiece detected by the imaging unit 230, the chuck table 172 is rotated, and the orientation of the cutting region in the workpiece with respect to the cutting blades 36 of the cutting units 174 is adjusted. Next, the chuck table 172 is moved in the X-axis direction by the X-axis feed mechanism 176, and the spindle housings 212 are moved in the Y-axis direction by the Y-axis feed mechanisms 178 to position the pair of cutting blades 36 above the cutting region in the workpiece.

Subsequently, the spindle housings 212 are lowered by the Z-axis feed mechanisms 180, and the cutting edges 40 of the cutting blades 36 rotated at high speed are caused to cut into the cutting region in the workpiece. In addition, processing feed of the chuck table 172 in the X-axis direction is executed while cutting water is supplied to the parts into which the cutting edges 40 of the cutting blades 36 are caused to cut. Thereby, predetermined cutting processing is executed for the cutting region in the workpiece. The above-described cutting processing is repeated as appropriate while indexing feed of the spindle housings 212 is executed in the Y-axis direction by the Y-axis feed mechanisms 178, and the cutting processing is executed for the whole of the cutting region in the workpiece. The cutting-processed workpiece for which the cutting step has been completed is conveyed to the next step.

When the cutting step is repeatedly executed, the cutting blade 36 wears. When the wear of the cutting blade 36 has reached a predetermined amount, the cutting accuracy is not kept, and therefore the cutting blade 36 mounted on the boss part 228 of the spindle 220 needs to be replaced by the new cutting blade 36. Furthermore, even in a case in which the wear of the cutting blade 36 mounted on the boss part 228 of the spindle 220 has not reached the predetermined amount, when cutting processing is executed for a workpiece of a material different from the material of the workpiece for which cutting processing has been executed previously, the need for replacement to the cutting blade 36 suitable for the material of the workpiece arises in some cases.

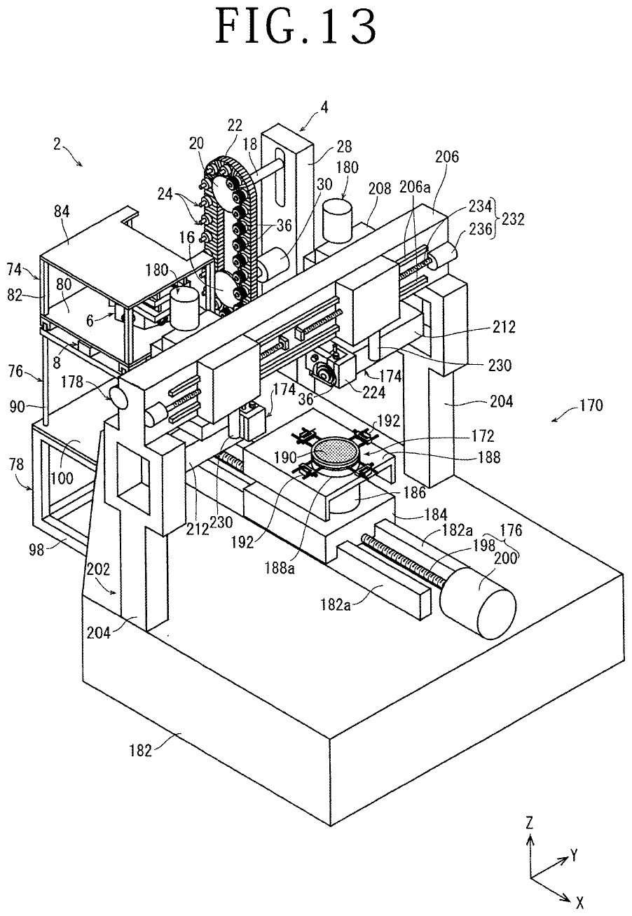

In the illustrated embodiment, as illustrated in FIG. 13, the cutting blade replacement apparatus 2 that can automatically replace the cutting blade 36 of the cutting apparatus 170 is mounted on the cutting apparatus 170. A method for replacing the cutting blades 36 by using the cutting blade replacement apparatus 2 will be described below.

As illustrated in FIG. 13, the cutting blade replacement apparatus 2 is disposed on the far side of the cutting apparatus 170 in the X-axis direction and can be mounted, from the back side, on the cutting apparatus 170 that has been already delivered to a user. When the cutting blades 36 mounted on the cutting apparatus 170 are replaced by using the cutting blade replacement apparatus 2, first, the endless track 22 of the cutting blade storage unit 4 is rotated, and the support shaft 24 that supports the new cutting blades 36 to be carried in to the cutting apparatus 170 is positioned to a predetermined position (for example, a position at the lowermost end in the trajectory of the support shaft 24).

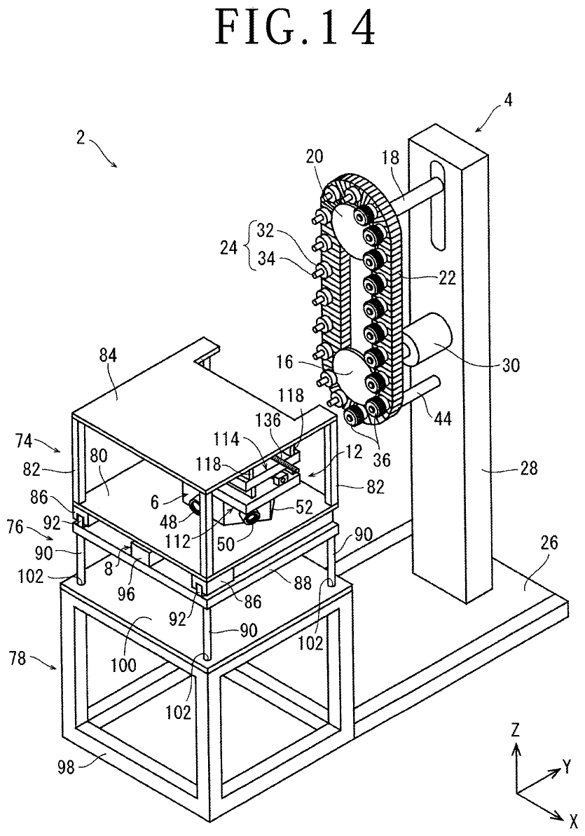

Subsequently, as illustrated in FIG. 14, by rotating the casing 52 by the motor coupled to the Z rotating shaft 46 of the nut attaching-detaching unit 6, the sidewall 56 of the casing 52 on which the blade holding part 48 is mounted is made to be along the X-axis direction, and the blade holding part 48 is caused to face the cutting blade storage unit 4. Furthermore, the X-axis movement mechanism 12 and the Z-axis movement mechanism 10 are actuated, and the position of the blade holding part 48 in the X-axis direction and the Z-axis direction is adjusted to allow the shaft part 34 of the support shaft 24 at the above-described predetermined position to be inserted into the central opening part 60 (see FIG. 5) of the blade holding part 48.

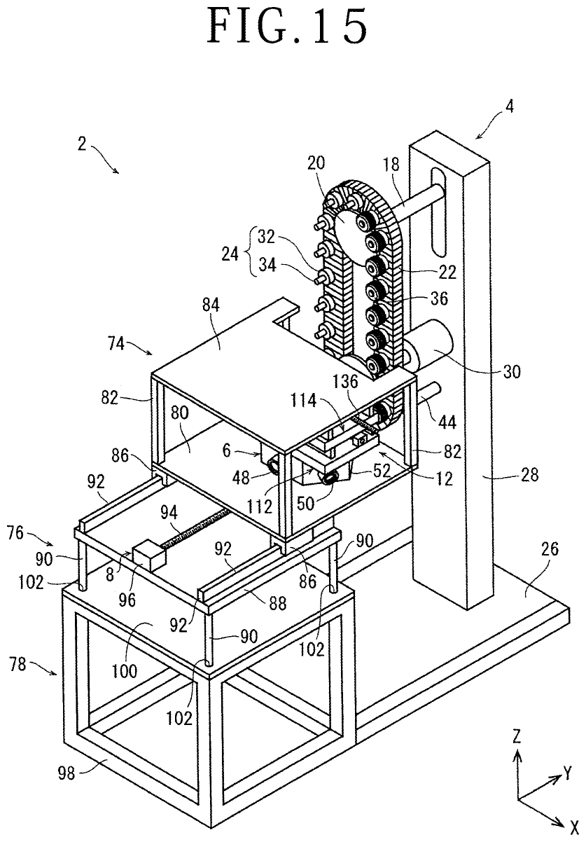

Next, as illustrated in FIG. 15, the frame body 74 is moved in the Y-axis direction by the Y-axis direction positioning mechanism 8, and the nut attaching-detaching unit 6 is positioned to the operation position at which the cutting blade 36 supported by the support shaft 24 can be held by the blade holding part 48. Thereby, the shaft part 34 of the support shaft 24 at the above-described predetermined position is inserted into the central opening part 60 of the blade holding part 48. In addition, the end surface 58 of the blade holding part 48 is brought into contact with the end surface of the cutting blade 36 located on the tip side of the shaft part 34. Subsequently, a suction force is generated for each suction hole 62 of the blade holding part 48, and the cutting blade 36 located on the tip side of the shaft part 34 is held under suction by the blade holding part 48.

Next, the Y-axis direction positioning mechanism 8 is actuated, and the nut attaching-detaching unit 6 is separated from the cutting blade storage unit 4 in the Y-axis direction and is positioned to the evacuation position. Subsequently, the casing 52 of the nut attaching-detaching unit 6 is rotated by 180° to cause the blade holding part 48 on the opposite side to the blade holding part 48 that holds the cutting blade 36 under suction to face the cutting blade storage unit 4.

Next, the Y-axis direction positioning mechanism 8 is actuated, and the nut attaching-detaching unit 6 is positioned to the operation position at which the cutting blade 36 of the support shaft 24 can be held by the blade holding part 48 on the opposite side. Subsequently, a suction force is generated for each suction hole 62 of the blade holding part 48 on the opposite side, and the cutting blade 36 located on the tip side of the shaft part 34 is held under suction by the blade holding part 48. This makes a state in which the new cutting blades 36 are held under suction by the pair of blade holding parts 48 opposed to each other in the four blade holding parts 48.

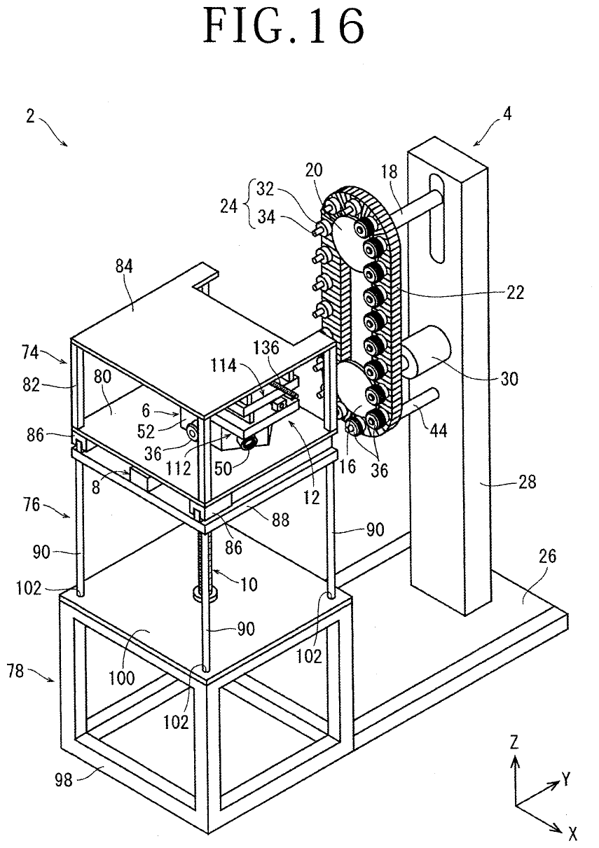

Next, as illustrated in FIG. 16, the frame body 74 is moved in the Y-axis direction by the Y-axis direction positioning mechanism 8. In addition, the raising-lowering table 76 is moved in the Z-axis direction by the Z-axis movement mechanism 10. Thereby, the nut attaching-detaching unit 6 is separated from the cutting blade storage unit 4 and is positioned to the evacuation position. In addition, the position of the nut attaching-detaching unit 6 in the Y-axis direction and the Z-axis direction relative to the cutting apparatus 170 is adjusted. The position of the nut attaching-detaching unit 6 in the Y-axis direction after the position adjustment is between the pair of cutting units 174 of the cutting apparatus 170, and the position of the nut attaching-detaching unit 6 in the Z-axis direction after the position adjustment is on the upper side relative to the holding surface of the chuck table 172.

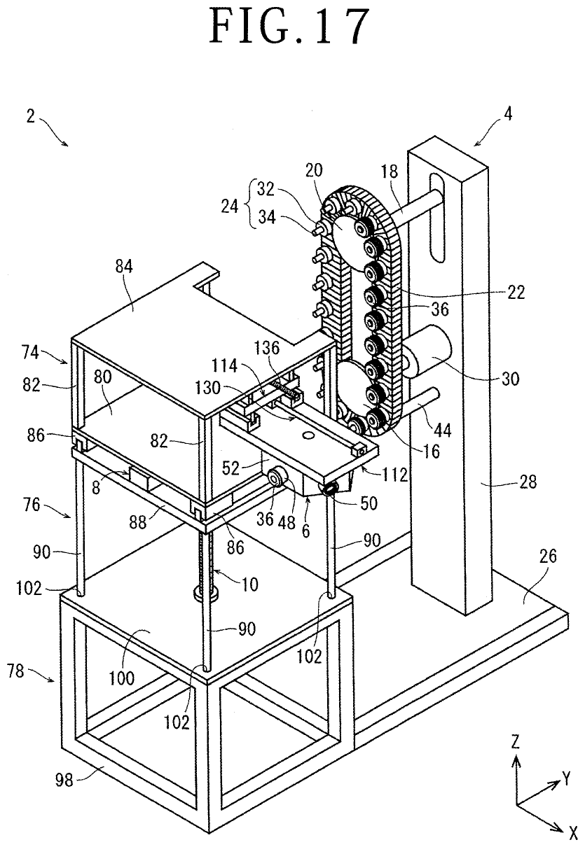

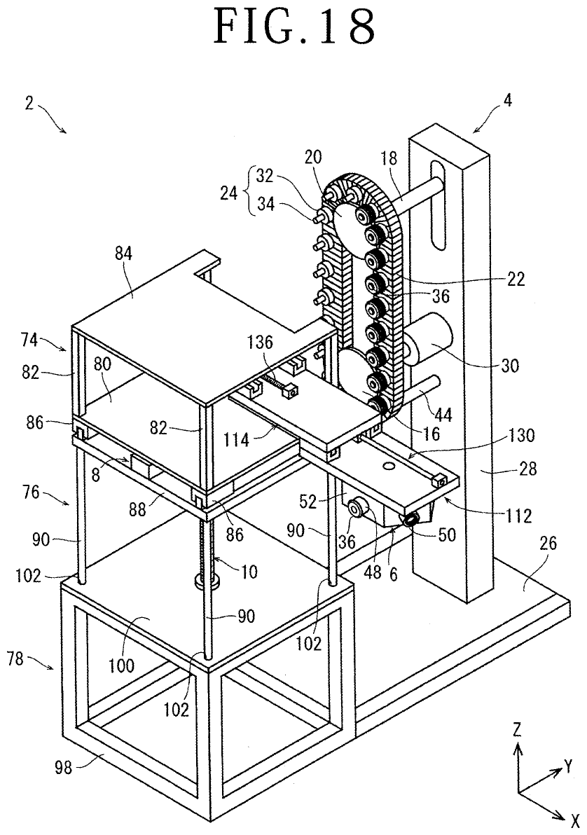

Subsequently, as illustrated in FIG. 17, the first moving body 112 is moved in the X-axis direction by the air cylinder 130 as the first X-axis movement mechanism, and the nut attaching-detaching unit 6 is caused to advance toward between the pair of cutting units 174 of the cutting apparatus 170. Next, as illustrated in FIG. 18, the second moving body 114 is moved in the X-axis direction by the second X-axis movement mechanism 136, and the position of the nut attaching-detaching unit 6 in the X-axis direction relative to the pair of cutting units 174 is adjusted.

Specifically, the position in the X-axis direction regarding the centers of the pair of new cutting blades 36 held under suction by the pair of blade holding parts 48 of the nut attaching-detaching unit 6 is aligned with the position in the X-axis direction regarding the centers of the pair of cutting blades 36 mounted in the pair of cutting units 174. Furthermore, the Z-axis movement mechanism 10 of the cutting blade replacement apparatus 2 or the Z-axis feed mechanisms 180 of the cutting apparatus 170 are actuated, and the position in the Z-axis direction regarding the centers of the cutting blades 36 of the blade holding parts 48 is aligned with the position in the Z-axis direction regarding the centers of the cutting blades 36 of the cutting units 174.

Next, the casing 52 of the nut attaching-detaching unit 6 is rotated by 60° to cause the pair of nut holding parts 50 to face the cutting blades 36 of the pair of cutting units 174. The casing 52 may be rotated by 60° before the first and second moving bodies 112 and 114 are caused to advance.

Subsequently, the second cover component 224b of the blade cover 224 of each of the pair of cutting units 174 is positioned to the opening position (see FIG. 11). Next, the cutting unit 174 is moved in the Y-axis direction by the Y-axis feed mechanism 178 of the cutting apparatus 170, and the nut 222 that fixes the cutting blade 36 to the boss part 228 of the spindle 220 is brought into contact with the end surface 66a of the rotating body 66 of the nut holding part 50. Thereupon, the pins 72 of the nut holding part 50 are pushed by the nut 222 and are housed inside the rotating body 66. In addition, the boss part 228 of the spindle 220 is housed in the central opening part 68 of the rotating body 66.

Next, when the rotating body 66 of the nut holding part 50 is rotated by the drive part of the nut attaching-detaching unit 6, each pin 72 is fitted into the pin hole 222a of the nut 222 when each pin 72 corresponds with the pin hole 222a, and the rotational motion of the rotating body 66 is transmitted to the nut 222 through each pin 72, and the nut 222 loosens. This can unscrew (detach) the nut 222 from the male screw 228a of the boss part 228 of the cutting unit 174. Furthermore, a suction force is generated for each suction hole 70 of the nut holding part 50, and the detached nut 222 is held under suction by the nut holding part 50.

Subsequently, the cutting unit 174 is separated from the nut attaching-detaching unit 6 by the Y-axis feed mechanism 178. In addition, the casing 52 of the nut attaching-detaching unit 6 is rotated by 60° to cause the empty blade holding part 48 that does not hold the cutting blade 36 under suction to face the cutting blade 36 of the cutting unit 174.

Next, the cutting unit 174 is brought close to the nut attaching-detaching unit 6 by the Y-axis feed mechanism 178, and the boss part 228 of the spindle 220 of the cutting unit 174 is inserted into the central opening part 60 of the blade holding part 48. In addition, the end surface 58 of the empty blade holding part 48 is brought into contact with the end surface of the cutting blade 36 of the cutting unit 174. Subsequently, a suction force is generated for each suction hole 62 of the blade holding part 48, and the cutting blade 36 of the cutting unit 174 is held under suction by the blade holding part 48.

Next, the cutting unit 174 is separated from the nut attaching-detaching unit 6 by the Y-axis feed mechanism 178. In addition, the casing 52 of the nut attaching-detaching unit 6 is rotated by 60° to cause the blade holding part 48 that holds the new cutting blade 36 under suction to face the boss part 228 of the spindle 220 of the cutting unit 174.

Subsequently, the cutting unit 174 is brought close to the nut attaching-detaching unit 6 by the Y-axis feed mechanism 178. Then, the boss part 228 of the spindle 220 is inserted into the central opening part 38a of the new cutting blade 36, and the end surface of the cutting blade 36 is brought into contact with the receiving part 226b of the flange 226 of the spindle 220. Next, the suction force of the blade holding part 48 is deactivated, and the new cutting blade 36 is transferred from the blade holding part 48 to the boss part 228 of the spindle 220.

Next, the cutting unit 174 is separated from the nut attaching-detaching unit 6 by the Y-axis feed mechanism 178. In addition, the casing 52 of the nut attaching-detaching unit 6 is rotated by 60° to cause the nut holding part 50 that holds the detached nut 222 under suction to face the boss part 228 of the spindle 220 of the cutting unit 174 as illustrated in FIG. 19.

Subsequently, the cutting unit 174 is brought close to the nut attaching-detaching unit 6 by the Y-axis feed mechanism 178, and the nut 222 held under suction by the nut holding part 50 is fitted to the boss part 228 of the spindle 220. Next, the drive part of the nut attaching-detaching unit 6 is actuated in the opposite direction to the direction when the nut 222 is detached, and the nut 222 is rotated to screw the nut 222 to the male screw 228a of the boss part 228.

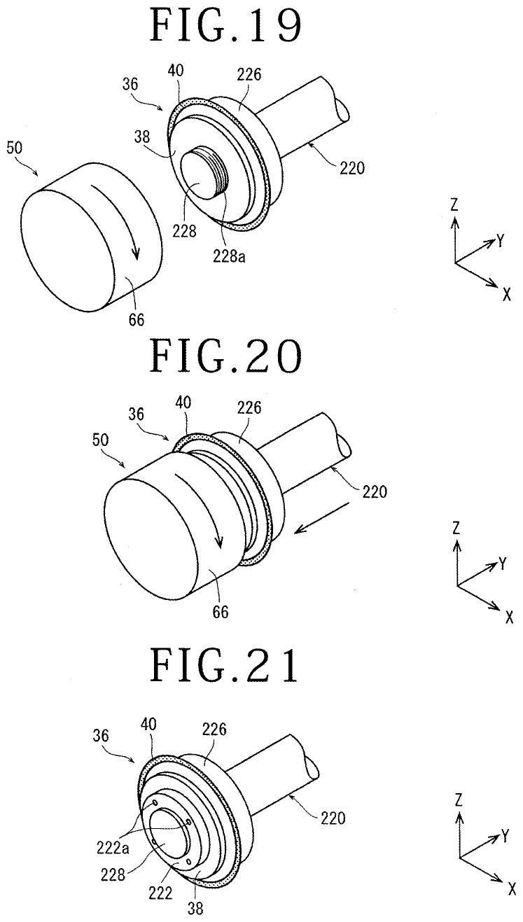

When the nut 222 is screwed to the male screw 228a of the boss part 228, as illustrated in FIG. 20, the cutting unit 174 having the boss part 228 is moved in the Y-axis direction by the Y-axis feed mechanism 178 of the cutting apparatus 170 in synchronization with the speed at which the boss part 228 moves in the Y-axis direction relative to the nut 222 due to the screwing of the nut 222 to the male screw 228a (speed at which the boss part 228 and the nut 222 relatively move in the Y-axis direction). The movement speed of the cutting unit 174 in this case is (pitch of the nut 222)×(rotation speed of the nut 222).

Alternatively, when the nut 222 is screwed to the male screw 228a, the nut attaching-detaching unit 6 that holds the nut 222 may be moved in the Y-axis direction by the Y-axis direction positioning mechanism 8 of the cutting blade replacement apparatus 2 in synchronization with the speed at which the nut 222 moves in the Y-axis direction relative to the boss part 228 due to the screwing of the nut 222 to the male screw 228a (speed at which the boss part 228 and the nut 222 relatively move in the Y-axis direction). The movement speed of the nut attaching-detaching unit 6 in this case is (pitch of the nut 222)×(rotation speed of the nut 222) as with the above-described cutting unit 174.

This can clamp the new cutting blade 36 that should be mounted in the cutting unit 174 by the receiving part 226b of the flange 226 of the spindle 220 and the nut 222 and fix the cutting blade 36 to the boss part 228 of the spindle 220.

Here, a description will be made about a case in which the center of the boss part 228 deviates from the center of the nut 222 when the nut 222 is screwed to the male screw 228a of the boss part 228.

In a case in which the center of the boss part 228 deviates from the center of the nut 222, if the cutting unit 174 is moved in the Y-axis direction by the Y-axis feed mechanism 178 and forcible screwing of the nut 222 to the male screw 228a is attempted, a pressing force equal to or larger than a predetermined value acts on the nut attaching-detaching unit 6 and the spindle housing 212 in the Y-axis direction because the nut 222 does not properly mesh with the male screw 228a.

As described above, the Y-axis direction positioning mechanism 8 of the cutting blade replacement apparatus 2 is configured in such a manner that, when the motor 96 has stopped, movement of the nut attaching-detaching unit 6 in the Y-axis direction together with the frame body 74 is permitted if a pressing force equal to or larger than the predetermined value acts on the nut attaching-detaching unit 6 in the Y-axis direction.

Thus, even when forcible screwing of the nut 222 to the male screw 228a is attempted by moving the cutting unit 174 having the boss part 228 in the Y-axis direction while rotating the nut 222 in a case in which the center of the boss part 228 deviates from the center of the nut 222, the nut attaching-detaching unit 6 moves due to the pressing force and escapes from the cutting unit 174, and therefore the nut 222 does not screw to the male screw 228a.

Furthermore, as described above, the Y-axis feed mechanism 178 of the cutting apparatus 170 is configured in such a manner that, when the motor 216 has stopped, movement of the spindle housing 212 in the Y-axis direction together with the Y-axis movable component 208 is permitted if a pressing force equal to or larger than the predetermined value acts on the spindle housing 212 in the Y-axis direction.

Thus, even when forcible screwing of the nut 222 to the male screw 228a is attempted by, conversely to the above, moving the nut attaching-detaching unit 6 that holds the nut 222 in the Y-axis direction while rotating the nut 222 in a case in which the center of the boss part 228 deviates from the center of the nut 222, the spindle housing 212 of the cutting unit 174 moves due to the pressing force and escapes from the nut attaching-detaching unit 6, and therefore the nut 222 does not screw to the male screw 228a.

Therefore, according to the illustrated embodiment, the nut 222 does not screw to the male screw 228a of the boss part 228 when the center of the boss part 228 deviates from the center of the nut 222. Therefore, the occurrence of galling between the male screw 228a and the nut 222 can be prevented, and the load applied to the nut 222 can be alleviated.

Furthermore, it is preferable that the configuration is made to issue a warning to the operator if the nut 222 has not screwed to the male screw 228a. For example, the warning may be implemented by displaying a warning screen on a monitor annexed to the cutting blade replacement apparatus 2 or the cutting apparatus 170. Alternatively, the warning may be implemented by issuing a warning sound from a speaker annexed to the cutting blade replacement apparatus 2 or the cutting apparatus 170. When the rotation of the rotating body 66 of the nut holding part 50 has continued for a predetermined time or longer, it can be determined that the nut 222 has not screwed to the male screw 228a.

The description about the replacement method of the cutting blades 36 will be resumed. After the nut 222 is screwed to the male screw 228a of the boss part 228, the suction force of the nut holding part 50 is deactivated. Subsequently, the second cover component 224b of the blade cover 224 of the cutting unit 174 is positioned to the closing position. The detachment and attachment of the nut 222 and the cutting blade 36 described above may be simultaneously executed for the pair of cutting units 174 or may be separately executed.

Next, the first and second moving bodies 112 and 114 are caused to retreat. In addition, the casing 52 of the nut attaching-detaching unit 6 is rotated by 60° to cause one of the pair of detached cutting blades 36 to face the cutting blade storage unit 4. Furthermore, the endless track 22 of the cutting blade storage unit 4 is rotated, and the empty support shaft 24 that does not support the cutting blade 36 is positioned to a predetermined position (for example, a position at the lowermost end in the trajectory of the support shaft 24).

Subsequently, the X-axis movement mechanism 12 and the Z-axis movement mechanism 10 are actuated, and the position of the blade holding part 48 in the X-axis direction and the Z-axis direction is adjusted to allow the shaft part 34 of the support shaft 24 at the above-described predetermined position to be inserted into the central opening part 38a of the one cutting blade 36 held under suction by the blade holding part 48.

Next, the frame body 74 is moved in the Y-axis direction by the Y-axis direction positioning mechanism 8, and the shaft part 34 of the support shaft 24 at the above-described predetermined position is inserted into the central opening part 38a of the one cutting blade 36 held under suction by the blade holding part 48. In addition, the end surface of the one cutting blade 36 is brought into contact with the end surface of the base part 32 of the support shaft 24. Subsequently, the suction force of the blade holding part 48 is deactivated, and the one of the pair of detached cutting blades 36 is transferred to the support shaft 24.

Furthermore, the nut attaching-detaching unit 6 is separated from the cutting blade storage unit 4 by the Y-axis direction positioning mechanism 8. In addition, the casing 52 of the nut attaching-detaching unit 6 is rotated by 180° to cause the blade holding part 48 on the opposite side that holds the other of the pair of detached cutting blades 36 under suction to face the cutting blade storage unit 4. Next, the frame body 74 is moved in the Y-axis direction by the Y-axis direction positioning mechanism 8, and the shaft part 34 of the support shaft 24 at the above-described predetermined position is inserted into the central opening part 38a of the other cutting blade 36 held under suction by the blade holding part 48 on the opposite side. In addition, the end surface of the other cutting blade 36 is brought into contact with the end surface of the cutting blade 36 supported by the support shaft 24. Subsequently, the suction force of the blade holding part 48 is deactivated, and the other of the pair of detached cutting blades 36 is transferred to the support shaft 24. In this manner, the cutting blades 36 of the cutting apparatus 170 can be replaced by using the cutting blade replacement apparatus 2.

The configuration of the embodiment is as described above. In the illustrated embodiment, when the nut 222 is screwed to the male screw 228a of the boss part 228, one of the nut attaching-detaching unit 6 and the spindle housing 212 of the cutting unit 174 moves in the Y-axis direction in synchronization with the speed of movement in the Y-axis direction due to the screwing of the nut 222, and the other of the nut attaching-detaching unit 6 and the spindle housing 212 of the cutting unit 174 is free (movable, allowed to escape) in the Y-axis direction. Therefore, the nut 222 does not screw to the male screw 228a of the boss part 228 when the center of the boss part 228 deviates from the center of the nut 222. Thus, the occurrence of galling between the male screw 228a and the nut 222 can be prevented. In addition, the load applied to the nut 222 can be alleviated.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting blade replacement apparatus mounted on a cutting apparatus including a chuck table that holds a workpiece, a cutting unit in which a cutting blade that cuts the workpiece held by the chuck table is mounted, an X-axis feed mechanism that executes processing feed in an X-axis direction, and a Y-axis feed mechanism that executes indexing feed in a Y-axis direction orthogonal to the X-axis direction, the cutting blade replacement apparatus being capable of attaching and detaching the cutting blade to and from the cutting unit,
the cutting unit having a spindle with a tip at which a flange is disposed and being configured in such a manner that mounting of the cutting blade is allowed by inserting a boss part that protrudes from a center of the flange into a central opening part of the cutting blade and screwing a nut to a male screw formed at an end part of the boss part,
the cutting blade replacement apparatus comprising:
a nut attaching-detaching unit including a nut holding part that holds the nut and a drive part that rotates the nut holding part, wherein
when the nut is screwed to the male screw formed at the end part of the boss part, one of the nut attaching-detaching unit and the cutting unit moves in the Y-axis direction in synchronization with a speed at which the boss part and the nut relatively move in the Y-axis direction due to the screwing of the nut, and the other of the nut attaching-detaching unit and the cutting unit escapes in the Y-axis direction when a pressing force equal to or larger than a predetermined value acts on the nut attaching-detaching unit or the cutting unit.

2. The cutting blade replacement apparatus according to claim 1, wherein
a warning is issued when the nut is not screwed.
